(19) United States
(12) Patent Application Publication
(10) Pub. No.: US 2023/0144685 A1
(43) Pub. Date: May 11, 2023

(54) APPARATUS FOR PROCESSING SUBSTRATE

(71) Applicant: SEMES CO., LTD., CHUNGCHEONGNAM-DO (KR)

(72) Inventors: Min Sung HAN, Gyeonggi-do (KR); Jae Hoo LEE, Gyeonggi-do (KR); Seong Hak BAE, Gyeongsangnam-do (KR)

(21) Appl. No.: 17/865,930

(22) Filed: Jul. 15, 2022

(30) Foreign Application Priority Data
Nov. 11, 2021 (KR) 10-2021-0154929

(51) Int. Cl. B23Q 3/08

(52) U.S. Cl. CPC B23Q 3/088; B23Q 2703/04

(57) ABSTRACT

A substrate processing apparatus including a substrate support unit connected to a vacuum pump to fix a substrate is provided. The substrate processing apparatus comprises a chamber including a processing space therein, a substrate support unit disposed in the processing space and for supporting a substrate, a first vacuum pump, a second vacuum pump connected to the processing space of the chamber, a first valve disposed between the first vacuum pump and the second vacuum pump, and a second valve disposed between the first vacuum pump and the substrate support unit, wherein the first vacuum pump reduces a pressure in a space between the substrate support unit and the substrate to fix the substrate to the substrate support unit in response to the second valve being turned on.

This application claims the benefit of Korean Patent Application No. 10-2021-0154929, filed on Nov. 11, 2021, in the Korean Intellectual Property Office, the disclosure of which is incorporated herein by reference in its entirety.

### BACKGROUND

### 1. Field

The present invention relates to a substrate processing apparatus.

### 2. Description of the Related Art

The semiconductor device manufacturing process may be continuously performed in a semiconductor manufacturing facility, and may be divided into a pre-process and a post-process. The semiconductor manufacturing facility may be installed in a space defined as a FAB to manufacture semiconductor devices.

The pre-process refers to a process of forming a circuit pattern on a wafer to complete a chip. These pre-processes may comprise a deposition process for forming a thin film on a substrate, a photo lithography process for transferring a photo resist onto a thin film using a photo mask, an etching process for selectively removing unnecessary parts using chemical substances or reactive gases in order to form a circuit pattern, an ashing process for removing the photoresist remaining after etching, an ion implantation process for implanting ions into the portion connected to a circuit pattern to have characteristics of an electronic device, a cleaning process for removing contamination sources from the substrate, and the like.

The post-process refers to the process of evaluating the performance of the finished product through the pre-process. The post-process may comprise a board inspection process that selects good and bad products by inspecting whether each chip on the board operates, the package process that cuts and separates each chip through dicing, die bonding, wire bonding, molding, and marking to shape the product, a final inspection process that finally checks the product characteristics and reliability through electrical characteristic inspection, and burn-in inspection, and the like.

When performing a substrate processing process, it is necessary to fix the substrate on the substrate support unit. As the structure of a substrate processing apparatus becomes simpler in recent years, a substrate support unit other than an electrostatic chuck may be used, and in this case, a method for fixing the substrate may be required.

### SUMMARY

An object of the present invention is to provide a substrate processing apparatus including a substrate support unit connected to a vacuum pump to fix a substrate.

An object of the present invention is to provide a substrate processing apparatus including a substrate support unit that improves efficiency of heat transfer to a substrate.

The objects of the present invention are not limited to the objects mentioned above, and other objects not mentioned will be clearly understood by those skilled in the art from the following description.

The substrate processing apparatus of the present invention for achieving the above object comprises a chamber including a processing space therein, a substrate support unit disposed in the processing space and for supporting a substrate, a first vacuum pump, a second vacuum pump connected to the processing space of the chamber, a first valve disposed between the first vacuum pump and the second vacuum pump, and a second valve disposed between the first vacuum pump and the substrate support unit, wherein the first vacuum pump reduces a pressure in a space between the substrate support unit and the substrate to fix the substrate to the substrate support unit in response to the second valve being turned on.

The substrate processing apparatus of the present invention for achieving the above object comprises a chamber including a processing space therein, a substrate support unit disposed in the processing space and for supporting a substrate, a first vacuum pump, a second vacuum pump connected to the first vacuum pump, a first valve connected between the second vacuum pump and the processing space of the chamber, and a second valve disposed between the second vacuum pump and the substrate support unit, wherein the second vacuum pump reduces a pressure in a space between the substrate support unit and the substrate to fix the substrate to the substrate support unit in response to the second valve being turned on.

The substrate processing apparatus of the present invention for achieving the above object comprises a chamber including a processing space therein, a substrate support unit disposed in the processing space and including an upper exposed hole and a flow path connected to the hole, a first vacuum pump connected to the processing space through a first valve, a second vacuum pump connected to the first vacuum pump through a second valve and connected to the processing space through a third valve, and a fourth valve connecting the flow path of the substrate support unit and the first vacuum pump, wherein the first vacuum pump reduces a pressure in the processing space in response to the first valve being turned on, wherein the second vacuum pump reduces a pressure in the processing space in response to the second valve and the third valve being turned on, wherein the first vacuum pump reduces a pressure of the flow path to fix the substrate to the substrate support unit in response to the substrate being mounted on the substrate support unit and the fourth valve being turned on, wherein the fourth valve is turned off after processing of the substrate is completed, wherein the substrate is carried out after the fourth valve is turned off.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram of a substrate processing apparatus according to some embodiments;

FIG. 2 is a stereoscopic view of the substrate support unit of FIG. 1;

FIG. 3 is a cross-sectional view of the substrate support unit taken along line A-A of FIG. 2;

FIGS. 4 and 5 are top views of a substrate support unit according to some embodiments;

FIG. 6 is a flowchart of a method of operating a substrate processing apparatus according to some embodiments;

FIGS. 7 to 9 are views for describing a method of operating a substrate processing apparatus according to some embodiments;

FIG. 10 is a flowchart illustrating a method of operating a substrate processing apparatus according to another exemplary embodiment;

FIG. 11 is a diagram of a substrate processing apparatus according to some embodiments; and

FIG. 12 is a diagram of a substrate processing apparatus according to some embodiments.

### DETAILED DESCRIPTION

Hereinafter, preferred embodiments of the present disclosure will be described in detail with reference to the accompanying drawings. Advantages and features of the present disclosure and methods of achieving them will become apparent with reference to the embodiments described below in detail in conjunction with the accompanying drawings. However, the present disclosure is not limited to the embodiments described below, but may be implemented in various different forms, and these embodiments are provided only for making the description of the present disclosure complete and fully informing those skilled in the art to which the present disclosure pertains on the scope of the present disclosure, and the present disclosure is only defined by the scope of the claims. Like reference numerals refer to like elements throughout.

Referring to an element or layer “on” another element or layer includes not only directly on the other element or layer, but also with intervening other layers or elements. On the other hand, referring to an element “directly on” indicates that no intervening element or layer is interposed.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

The terminology used herein is for the purpose of describing the embodiments and is not intended to limit the present invention. In this specification, the singular also includes the plural unless otherwise specified in the phrase. As used herein, “comprises” refers to the presence or addition of one or more other components, steps, operations and/or elements mentioned is not excluded.

Unless otherwise defined, all terms (including technical and scientific terms) used herein may be used with the meaning commonly understood by those of ordinary skill in the art, to which the present invention belongs. In addition, terms defined in a commonly used dictionary are not to be interpreted ideally or excessively unless clearly specifically defined.

Hereinafter, embodiments of the present disclosure will be described in detail with reference to the accompanying drawings, and in the description with reference to the accompanying drawings, the same or corresponding components are given the same reference numbers, regardless of reference numerals in drawings, and an overlapped description therewith will be omitted.

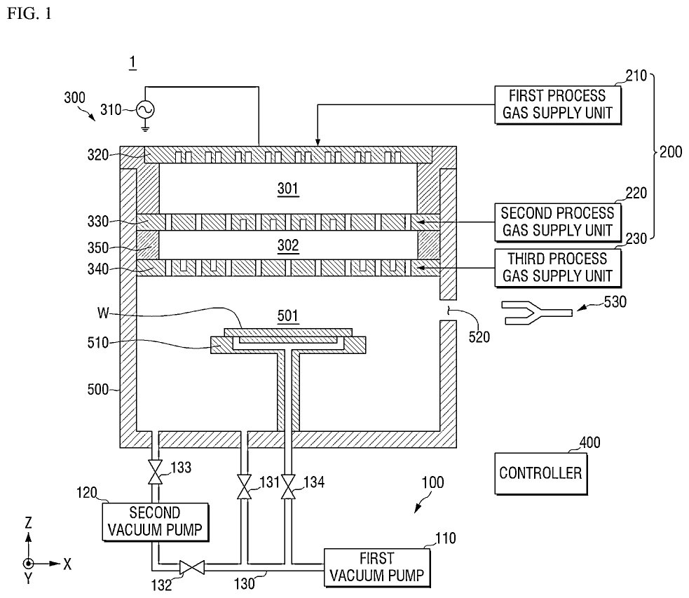

FIG. 1 is a diagram of a substrate processing apparatus according to some embodiments.

Referring to FIG. 1, a substrate processing apparatus 1 may comprise an exhaust device 100, a gas supply device 200, an electrode module 300, a controller 400, and a chamber 500.

The chamber 500 may provide a processing space 501 therein, in which the substrate W is processed. Here, the chamber 500 may have a circular cylindrical shape. The chamber 500 may include a metal material. For example, the chamber 500 may be made of aluminum. The opening 520 may be formed at one side of the chamber 500. The opening 520 may correspond to an entrance, through which the substrate W can be carried in and out. Here, the opening 520 may be opened and closed by a door.

The transfer robot 530 may pass through the opening 520 to carry in or out the substrate W. For example, when the opening 520 is opened, the transfer robot 530 may pass through the opening 520 to place the substrate W on the substrate support unit 510 in the processing space 501. After the process for the substrate W is finished, the transfer robot 530 may carry out the substrate W from the substrate support unit 510. At this time, the transfer robot 530 may pass through the opening 520.

The chamber 500 may include a substrate support unit 510 disposed in the processing space 501. Here, the substrate support unit 510 may be referred to as a chuck. The substrate support unit 510 may support the substrate W and may fix the substrate W so that the substrate W does not move. Also, the substrate support unit 510 may include a heater for heating the substrate W. Here, the substrate support unit 510 may be located in the central portion of the chamber 500. The substrate support unit 510 may be connected to the exhaust device 100, but may not be connected to the gas supply device 200 and the electrode module 300. However, embodiments of the present invention are not limited thereto.

The gas supply device 200 may include a first process gas supply unit 210, a second process gas supply unit 220, and a third process gas supply unit 230. The first to third process gas supply units 210, 220, 230 may provide different gases to the electrode module 300 and the chamber 500. For example, the first process gas supply unit 210 may generate a gas used in the first process, the second process gas supply unit 220 may generate a gas used in the second process, and the third process gas supply unit 230 may generate a gas used in the third process.

The electrode module 300 may include a high frequency power supply 310, an electrode 320, an ion blocker 330, a shower head 340, a heater ring 350, and the like. The electrode module 300 may generate plasma using the gas provided from the gas supply device 200 and provide it to the processing space 501.

A first space 301 may be formed between the electrode 320 and the ion blocker 330, and a second space 302 may be formed between the ion blocker 330 and the shower head 340. A processing space 501 may be formed under the shower head 340.

The electrode 320 may be connected to the high frequency power supply 310, and the ion blocker 330 may be connected to a constant voltage. The electrode 320 may include a plurality of supply holes. The first process gas supply unit 210 may provide the first process gas to the first space 301 through the electrode 320.

The electromagnetic field generated between the electrode 320 and the ion blocker 330 may excite the first process gas to a plasma state. The first process gas excited into a plasma state (e.g., plasma effluent) may include radicals, ions, and/or electrons. The first process gas may vary depending on the target material. For example, when the target material includes silicon oxide formed on the substrate W, the first process gas may be nitrogen trifluoride (NF3), and may further include an inert gas (e.g., He).

The ion blocker 330 may include a conductive material and may have a disk shape. The ion blocker 330 may include a plurality of first through holes. In the plasma effluent, radicals may pass through the first through holes of the ion blocker 330. On the other hand, the charged ions cannot pass through the first through holes of the ion blocker 330.

The second process gas supply unit 220 may provide the second process gas to the ion blocker 330, thereby providing the second process gas to the second space 302.

The shower head 340 may include a conductive material and may have a disk shape. The shower head 340 may include a plurality of second through holes. The shower head 340 may provide a gas to the processing space 501 through the second through holes.

The third process gas supply unit 230 may provide the third process gas to a supply port formed in the shower head 340, and through this, the third process gas may be provided to the second space 302.

The heater ring 350 may be disposed between the ion blocker 330 and the shower head 340 and surround the second space 302. The heater ring 350 may control the temperature of the shower head 340.

In an embodiment of the present invention, the substrate W may be disposed on the substrate support unit 510. However, depending on the process, the substrate W may be carried out from the substrate support unit 510.

The exhaust device 100 may comprise a first vacuum pump 110, a second vacuum pump 120, a flow path 130, a first valve 131, a second valve 132, a third valve 133, and a fourth valve 134. The exhaust device 100 may be disposed under the chamber 500 and may be directly connected to the chamber 500. For example, the exhaust device 100 may be directly connected to the processing space 501 and the substrate support unit 510. The exhaust device 100 may not be directly connected to the gas supply device 200 and the electrode module 300.

While the exhaust device 100 performs a function of absorbing gas and discharging gas, the gas supply device 200 may perform a function of discharging gas without absorbing gas. That is, the exhaust device 100 and the gas supply device 200 may be separated from each other and perform different functions.

Here, the controller 400 may control overall operations of the exhaust device 100, the gas supply device 200, and the electrode module 300.

The first vacuum pump 110 may exhaust gas or particles in the processing space 501 through the flow path 130. For example, the flow path 130 connected to the first vacuum pump 110 may be connected to the first valve 131, and the first valve 131 may be connected to the chamber 500. When the first valve 131 is turned off, the first vacuum pump 110 cannot exhaust gas in the processing space 501. When the first valve 131 is turned on, the first vacuum pump 110 may exhaust gas in the processing space 501 through the flow path 130. Accordingly, the pressure of the processing space 501 may decrease from atmospheric pressure to a pressure close to 0 atm. Here, the first vacuum pump 110 may include a dry pump.

The second vacuum pump 120 may exhaust gas or particles in the processing space 501. For example, the second vacuum pump 120 may be connected to the first vacuum pump 110 through the second valve 132. Also, the second vacuum pump 120 may be connected to the chamber 500 through the third valve 133. When the second valve 132 and the third valve 133 are turned on, the second vacuum pump 120 may exhaust gas in the processing space 501 through the flow path 130. The gas exhaust of the second vacuum pump 120 may be performed later than that of the first vacuum pump 110. The second vacuum pump 120 may make the pressure of the processing space 501 having a pressure close to 0 atm a vacuum. In this case, the second and third valves 132 and 133 may be turned on later than the first valve 131. That is, after the first vacuum pump 110 operates, the second vacuum pump 120 may operate. The first vacuum pump 110 may exhaust gas, particles, etc. absorbed from the second vacuum pump 120. Here, the second vacuum pump 120 may include a turbo molecular pump.

The fourth valve 134 may be disposed between the first vacuum pump 110 and the substrate support unit 510. The fourth valve 134 may connect the first vacuum pump 110 and the substrate support unit 510. For example, the fourth valve 134 may be connected to the first vacuum pump 110 through the flow path 130, and may be connected to the flow path formed inside the substrate support unit 510. Here, the flow path formed inside the substrate support unit 510 may be exposed in an upper portion of the substrate support unit 510. That is, the flow path may be connected to a hole in an upper portion of the substrate support unit 510. The hole in the upper portion of the substrate support unit 510 may directly contact the substrate W. That is, the flow path of the substrate support unit 510 may be formed between the substrate W and the fourth valve 134.

When the fourth valve 134 is turned on, the first vacuum pump 110 may absorb the gas in the space between the substrate support unit 510 and the substrate W. That is, the first vacuum pump 110 may reduce the pressure of the flow path. Accordingly, the substrate support unit 510 may adsorb the substrate W, and the substrate W may be fixed to the substrate support unit 510. Here, the fourth valve 134 may be turned on after the first to third valves 131 to 133 are turned on. That is, after the processing space 501 becomes vacuum, the fourth valve 134 may be turned on, and the first vacuum pump 110 may fix the substrate W to the substrate support unit 510. However, the embodiment of the present invention is not limited thereto, and the operation order of the first to fourth valves 131 to 134 may be different from this.

When the fourth valve 134 is turned off, the first vacuum pump 110 may not absorb the gas in the space between the substrate support unit 510 and the substrate W. That is, the substrate support unit 510 may not adsorb the substrate W. Accordingly, the substrate W may not be fixed to the substrate support unit 510 and may be detached.

Accordingly, the substrate W may be fixed to the substrate support unit 510 during the process. Also, after completion of the process, the substrate W may be carried out without being fixed from the substrate support unit 510. That is, even if no voltage is applied to the substrate support unit 510, the substrate W may be fixed to the substrate support unit 510. In addition, substrate processing apparatus 1 including the substrate support unit 510 having a simpler structure may be provided by fixing the substrate W to the substrate support unit 510 using the first vacuum pump 110 and the fourth valve 134.

In addition, since the substrate W is fixed to the substrate support unit 510, heat generated from the substrate support unit 510 may be transferred to the substrate W. That is, the substrate processing apparatus 1 including the substrate support unit 510 that improves the efficiency of heat transfer to the substrate W may be provided.

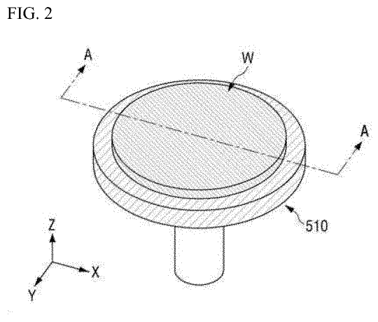

Hereinafter, the substrate support unit 510 will be described in more detail with reference to FIGS. 2 to 5.

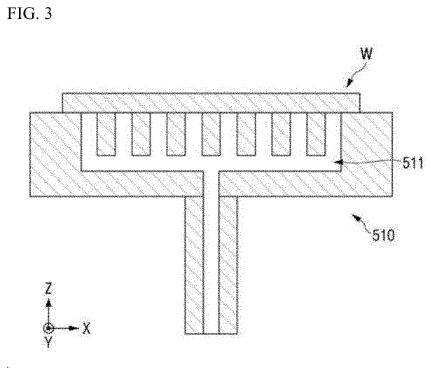

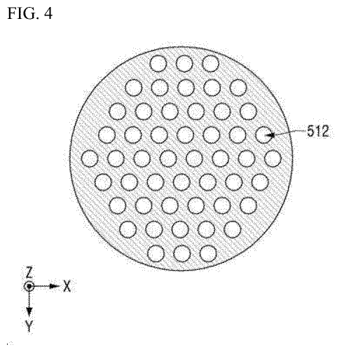

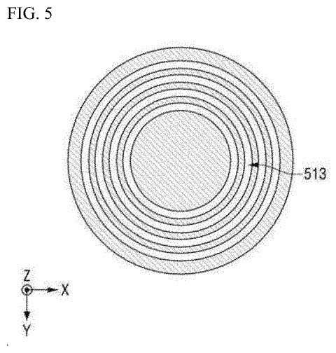

FIG. 2 is a stereoscopic view of the substrate support unit of FIG. 1. FIG. 3 is a cross-sectional view of the substrate support unit taken along line A-A of FIG. 2. FIGS. 4 and 5 are top views of a substrate support unit in accordance with some embodiments.

Referring to FIGS. 2 and 3, the substrate support unit 510 may have a cylindrical shape. For example, the substrate support unit 510 may have a shape of a first cylinder connected to the chamber 500 and a second cylinder connected on the first cylinder. However, embodiments of the present invention are not limited thereto.

The substrate W may be disposed on the substrate support unit 510. In this case, the substrate W may be connected to the flow path 511 of the substrate support unit 510. The substrate support unit 510 may include a flow path 511 therein. The flow path 511 may correspond to a space between the fourth valve 134 and the substrate W. When the fourth valve 134 is turned on, the gas inside the flow path 511 may be exhausted to the outside by the first vacuum pump 110. Accordingly, the pressure of the flow path 511 may be a vacuum, and the substrate W may be adsorbed to the substrate support unit 510.

In this case, the flow path 511 may include a plurality of holes in the upper portion of the substrate support unit 510. Referring to FIG. 4, the substrate support unit 510 may include a plurality of adsorption holes 512. Here, the plurality of adsorption holes 512 may be scattered on the upper surface of the substrate support unit 510. Accordingly, as the gas inside the adsorption hole 512 is exhausted, the substrate W may be adsorbed to the substrate support unit 510.

Referring to FIG. 5, the substrate support unit 510 may include a plurality of adsorption holes 513. Here, the plurality of adsorption holes 513 may have a plurality of concentric circles disposed on the upper surface of the substrate support unit 510. As the gas inside the adsorption hole 513 is exhausted, the substrate W may be adsorbed to the substrate support unit 510.

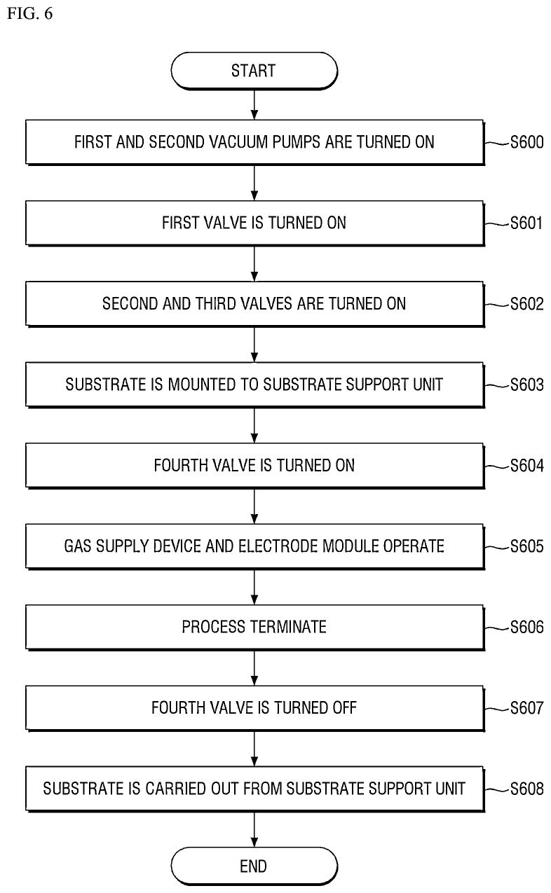

Hereinafter, an operation method of the substrate processing apparatus 1 will be described with reference to FIGS. 6 to 9.

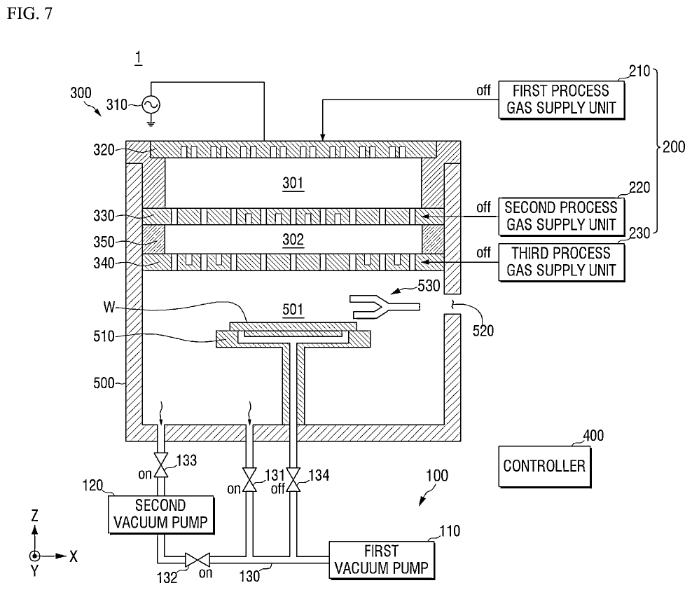

FIG. 6 is a flowchart of a method of operating a substrate processing apparatus according to some embodiments. FIGS. 7 to 9 are views for describing a method of operating a substrate processing apparatus according to some embodiments.

Referring to FIGS. 6 and 7, first and second vacuum pumps 110 and 120 may be turned on (S600). At this time, the first to fourth valves 131 to 134 may be turned off. That is, the pressure of the processing space 501 may be maintained at atmospheric pressure.

Thereafter, the first valve 131 may be turned on (S601). As the first valve 131 is turned on, the first vacuum pump 110 may absorb the gas in the processing space 501.

Accordingly, the pressure in the processing space 501 may be close to 0 atm.

Thereafter, the second and third valves 132 and 133 may be turned on (S602). As the second and third valves 132 and 133 are turned on, the second vacuum pump 120 may be connected to the first vacuum pump 110 and may absorb gas in the processing space 501. The processing space 501 may be maintained in a vacuum state by the first vacuum pump 110 and the second vacuum pump 120.

Thereafter, the substrate W may be mounted on the substrate support unit 510 (S603). The transfer robot 530 may mount the substrate W on the substrate support unit 510. In this case, the substrate W may directly contact the adsorption hole of the substrate support unit 510.

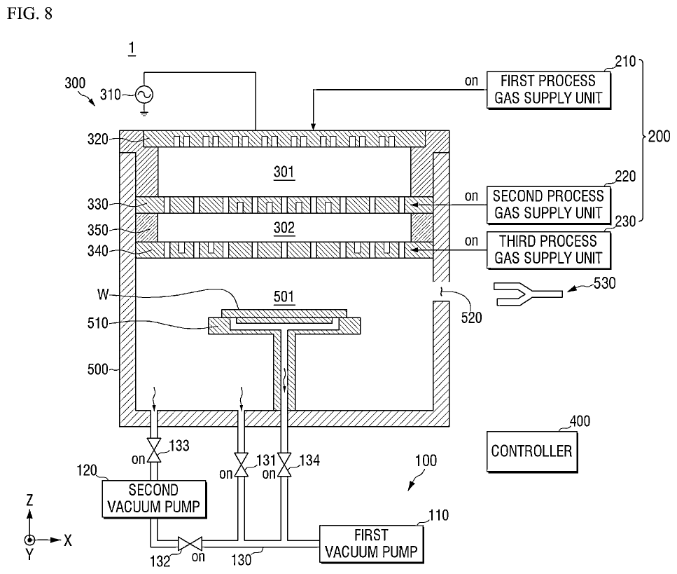

Referring to FIGS. 6 and 8, the fourth valve 134 may be turned on (S604). As the fourth valve 134 is turned on, the first vacuum pump 110 may absorb the gas in the substrate support unit 510. Accordingly, the substrate W may be fixed to the substrate support unit 510. In addition, heat generated from the substrate support unit 510 may be transferred to the substrate W. Accordingly, the position of the substrate W may be fixed during the process.

Thereafter, the gas supply device 200 and the electrode module 300 may operate (S605). Accordingly, plasma generated in the first space 301 and the second space 302 may be provided to the processing space 501. Accordingly, a processing process for the substrate W may be performed.

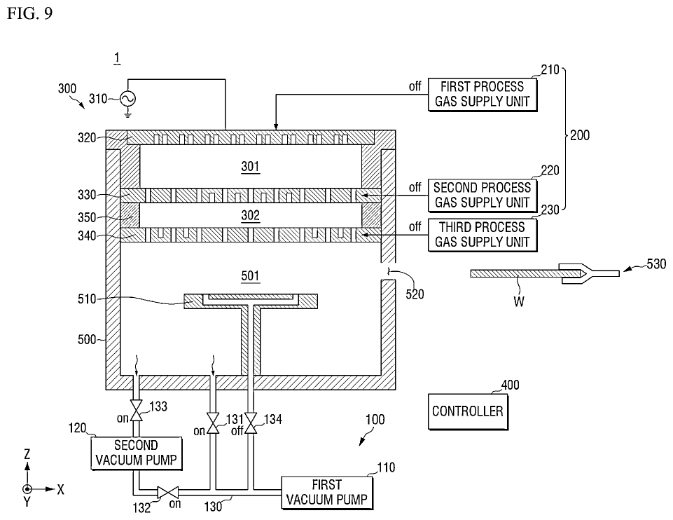

Referring to FIGS. 6 and 9, the process may be terminated (S606). That is, the processing process for the substrate W may be terminated.

Subsequently, the fourth valve 134 may be turned off (S607). Accordingly, the first vacuum pump 110 may not absorb the gas in the substrate support unit 510. Accordingly, the space between the substrate support unit 510 and the substrate W cannot be maintained in a vacuum. Accordingly, the substrate W is not fixed to the substrate support unit 510. At this time, the first to third valves 131 to 133 may maintain a turned-on state. That is, the processing space 501 may be maintained in a vacuum.

Subsequently, the substrate W may be carried out from the substrate support unit 510 (S608). The transfer robot 530 may carry out the substrate W on the substrate support unit 510. At this time, since the substrate W is not fixed to the substrate support unit 510, it may be freely carried out. As described above, the substrate W may be fixed to the substrate support unit 510 through the first vacuum pump 110 and the fourth valve 134.

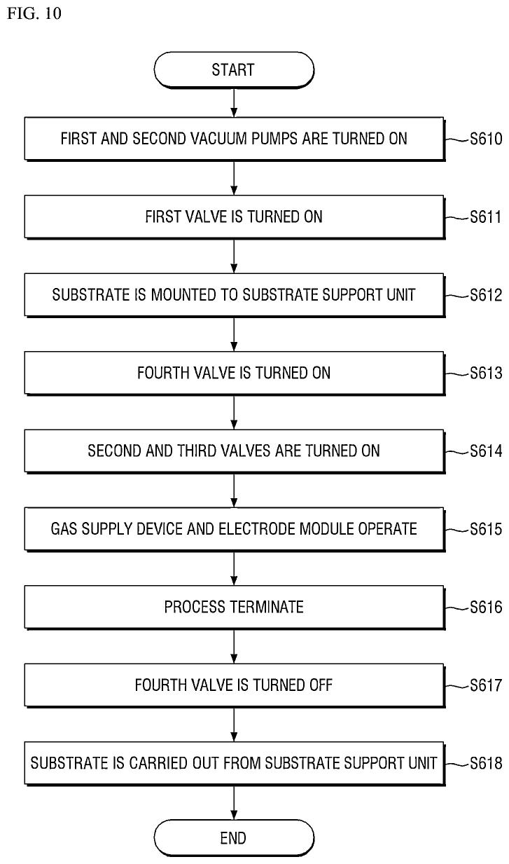

FIG. 10 is a flowchart illustrating a method of operating a substrate processing apparatus according to another exemplary embodiment.

Referring to FIGS. 1 and 10, the first and second vacuum pumps 110 and 120 may be turned on (S610). Thereafter, the first valve 131 may be turned on (S611). Accordingly, the pressure in the processing space 501 may be close to 0 atm. At this time, the second to fourth valves 132 to 134 may be turned off.

Subsequently, the substrate W may be mounted on the substrate support unit 510 (S612). Thereafter, the fourth valve 134 may be turned on (S613). Accordingly, the substrate W may be fixed to the substrate support unit 510. After the substrate W is fixed, the second and third valves 132 and 133 may be turned on (S614). Accordingly, the second vacuum pump 120 may maintain the processing space 501 in a vacuum state.

Subsequently, the gas supply device 200 and the electrode module 300 may operate (S615), and after the process ends (S616), the fourth valve 134 may be turned off (S617). Accordingly, the substrate W may not be fixed to the substrate support unit 510. Subsequently, the substrate W may be carried out from the substrate support unit 510 (S618).

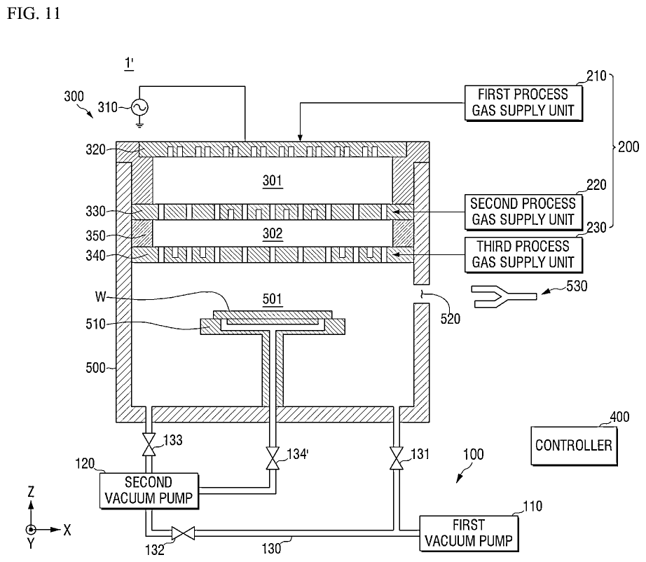

Hereinafter, a substrate processing apparatus 1′ according to another exemplary embodiment will be described with reference to FIG. 11. Among the contents described above with reference to FIGS. 1 to 10, overlapping contents will be omitted.

FIG. 11 is a diagram of a substrate processing apparatus according to some embodiments.

Referring to FIG. 11, the exhaust device 100 may include a first vacuum pump 110, a second vacuum pump 120, a first valve 131, a second valve 132, a third valve 133 and a fourth valves 134′.

Here, the first valve 131 may connect the first vacuum pump 110 and the chamber 500, and the second valve 132 may connect the first vacuum pump 110 and the second vacuum pump 120. The third valve 133 may connect the second vacuum pump 120 and the chamber 500. Also, the fourth valve 134′ may connect the second vacuum pump 120 and the substrate support unit 510.

In this case, when the fourth valve 134′ is turned off, the substrate support unit 510 may not fix the substrate W. A space between the fourth valve 134′ and the substrate support unit 510 may not be maintained in a vacuum.

When the fourth valve 134′ is turned on, the second vacuum pump 120 may reduce the pressure in the space between the substrate support unit 510 and the substrate W. Accordingly, the substrate W may be fixed to the substrate support unit 510. Unlike the substrate processing apparatus 1 described with reference to FIGS. 1 to 10, in which the first vacuum pump 110 reduces the pressure of the space between the substrate support unit 510 and the substrate W, the substrate processing apparatus 1′ described with reference to FIG. 11 may fix the substrate W by the second vacuum pump 120. That is, the substrate support unit 510 of the substrate processing apparatus 1′ may not be directly connected to the first vacuum pump 110.

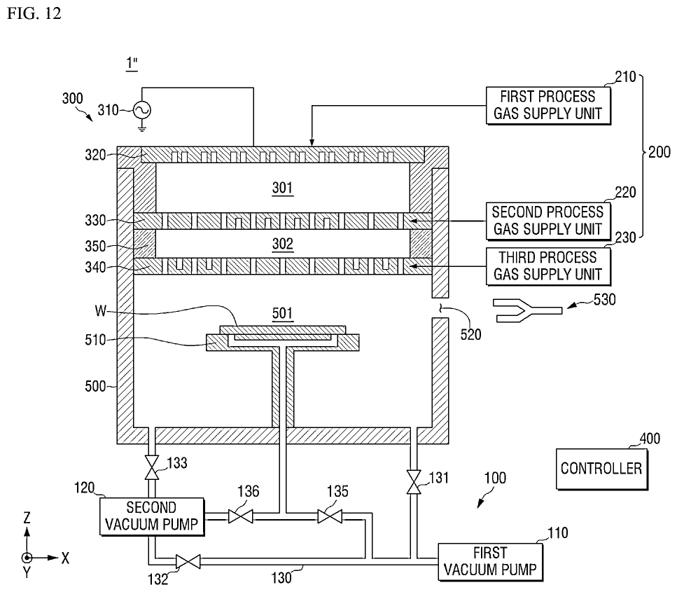

Hereinafter, a substrate processing apparatus 1″ according to another exemplary embodiment will be described with reference to FIG. 12. Among the contents described above with reference to FIGS. 1 to 10, overlapping contents will be omitted.

FIG. 12 is a diagram of a substrate processing apparatus according to some embodiments.

Referring to FIG. 12, the exhaust device 100 of the substrate processing apparatus 1″ may include a first vacuum pump 110, a second vacuum pump 120, a first valve 131, a second valve 132, a third valve 133, a fifth valve 135, and a sixth valve 136.

Here, the fifth valve 135 may connect the first vacuum pump 110 and the substrate support unit 510, and the sixth valve 136 may connect the second vacuum pump 120 and the substrate support unit 510. Also, the fifth valve 135 and the sixth valve 136 may be connected to each other through a flow path.

When the fifth valve 135 is turned on, the first vacuum pump 110 may fix the substrate W to the substrate support unit 510. When the fifth valve 135 is turned on, the second vacuum pump 120 may fix the substrate W to the substrate support unit 510. When the fifth and sixth valves 135 and 136 are turned on, the first and second vacuum pumps 110 and 120 may fix the substrate W to the substrate support unit 510. When both the fifth and sixth valves 135 and 136 are turned off, the first and second vacuum pumps 110 and 120 may fix the substrate W to the substrate support unit 510.

In summary, when at least one of the fifth and sixth valves 135 and 136 is turned on, the substrate W may be fixed to the substrate support unit 510. However, embodiments of the present invention are not limited thereto.

Although embodiments of the present invention have been described with reference to the above and the accompanying drawings, those skilled in the art, to which the present invention pertains, can understand that the present invention may be practiced in other specific forms without changing its technical spirit or essential features. Therefore, it should be understood that the embodiments described above are illustrative in all respects and not limiting.

What is claimed is:

1. An apparatus for processing a substrate comprising:
a chamber including a processing space therein;
a substrate support unit disposed in the processing space and for supporting a substrate;
a first vacuum pump;
a second vacuum pump connected to the processing space of the chamber;
a first valve disposed between the first vacuum pump and the second vacuum pump; and
a second valve disposed between the first vacuum pump and the substrate support unit,
wherein the first vacuum pump reduces a pressure in a space between the substrate support unit and the substrate to fix the substrate to the substrate support unit in response to the second valve being turned on.

2. The apparatus of claim 1 further comprises,
a third valve disposed between the first vacuum pump and the processing space,
wherein the first vacuum pump reduces a pressure in the processing space in response to the third valve being turned on.

3. The apparatus of claim 2, wherein the third valve is turned on before the second valve.

4. The apparatus of claim 2, wherein the substrate is separated from the substrate support unit in response to the second valve being turned off,
wherein the third valve is turned off after the second valve is turned off.

5. The apparatus of claim 1 further comprises,
a fourth valve disposed between the second vacuum pump and the processing space,
wherein the first vacuum pump is connected to the second vacuum pump in response to the first valve being turned on.

6. The apparatus of claim 5, wherein the second vacuum pump reduces a pressure in the processing space in response to the fourth valve being turned on,
wherein the first valve is turned on before the fourth valve.

7. The apparatus of claim 6, wherein the fourth valve is turned on before the second valve.

8. The apparatus of claim 1, wherein the substrate support unit includes a flow path between the second valve and the substrate,
wherein the first vacuum pump absorbs a gas in the flow path.

9. The apparatus of claim 1 further comprises,
a gas supply unit for supplying a gas to the processing space,
wherein the gas supply unit discharges a gas, and the first and second vacuum pumps absorb a gas.

10. The apparatus of claim 9, wherein a space between the substrate support unit and the substrate is not connected to the gas supply unit.

11. The apparatus of claim 1 further comprises,
a fifth valve disposed between the second vacuum pump and the substrate support unit,
wherein the second vacuum pump reduces a pressure in a space between the substrate support unit and the substrate to fix the substrate to the substrate support unit in response to the fifth valve being turned on.

12. The apparatus of claim 11, wherein the second valve is turned off in response to the fifth valve being turned on.

13. The apparatus of claim 11, wherein at least one of the second valve and the fifth valve is turned on.

14. The apparatus of claim 1, wherein the first vacuum pump includes a dry pump, and the second vacuum pump includes a turbo molecular pump.

15. An apparatus for processing a substrate comprising:
a chamber including a processing space therein;
a substrate support unit disposed in the processing space and for supporting a substrate;
a first vacuum pump;
a second vacuum pump connected to the first vacuum pump;
a first valve connected between the second vacuum pump and the processing space of the chamber; and
a second valve disposed between the second vacuum pump and the substrate support unit,
wherein the second vacuum pump reduces a pressure in a space between the substrate support unit and the substrate to fix the substrate to the substrate support unit in response to the second valve being turned on.

16. The apparatus of claim 15, wherein the second vacuum pump reduces a pressure in the processing space in response to the first valve being turned on,
wherein the first valve is turned on before the second valve.

17. The apparatus of claim 16 further comprises,
a third valve connected between the first vacuum pump and the processing space,
wherein the third valve is turned on before the first valve.

18. An apparatus for processing a substrate comprising:
a chamber including a processing space therein;
a substrate support unit disposed in the processing space and including an upper exposed hole and a flow path connected to the hole;
a first vacuum pump connected to the processing space through a first valve;
a second vacuum pump connected to the first vacuum pump through a second valve and connected to the processing space through a third valve; and
a fourth valve connecting the flow path of the substrate support unit and the first vacuum pump,
wherein the first vacuum pump reduces a pressure in the processing space in response to the first valve being turned on,
wherein the second vacuum pump reduces a pressure in the processing space in response to the second valve and the third valve being turned on,
wherein the first vacuum pump reduces a pressure of the flow path to fix the substrate to the substrate support unit in response to the substrate being mounted on the substrate support unit and the fourth valve being turned on,
wherein the fourth valve is turned off after processing of the substrate is completed,
wherein the substrate is carried out after the fourth valve is turned off.

19. The apparatus of claim 18 further comprises,
a gas supply unit for supplying a gas to the processing space,
wherein the gas supply unit discharges a gas, and the first and second vacuum pumps absorb a gas.

20. The apparatus of claim 19, wherein the first vacuum pump, the second vacuum pump, and the flow path are not directly connected to the gas supply unit.
